(19) United States
(12) Patent Application Publication
(10) Pub. No.: US 2009/0014319 A1
(43) Pub. Date: Jan. 15, 2009

(54) TRANSPARENT INSULATING FILM, METHOD FOR PRODUCING THE SAME, AND SPUTTERING TARGET

(75) Inventors: Shina Kirita, Tokyo (JP); Toshitaka Kawashima, Kanagawa (JP)

Correspondence Address: BELL, BOYD & LLOYD, LLP, P. O. BOX 1135, CHICAGO, IL, 60690, US

(73) Assignee: SONY CORPORATION, Tokyo (JP)

(21) Appl. No.: 12/166,471

(22) Filed: Jul. 2, 2008

(30) Foreign Application Priority Data
Jul. 12, 2007 (JP) P2007-183115

(51) Int. Cl. C23C 14/14

(52) U.S. Cl. 204/192.22; 204/298.13

(57) ABSTRACT

A method for producing a transparent insulating film includes a step of forming a transparent insulating film on a substrate by sputtering using a zinc-aluminum alloy target containing 50% to 90% by weight zinc and 10% to 50% byt weight aluminum in a mixed gas atmosphere of an inert gas and oxygen gas.

### CROSS REFERENCES TO RELATED APPLICATIONS

The present application claims priority to Japanese Patent Application JP 2007-183115 filed in the Japanese Patent Office on Jul. 12, 2007, the entire contents of which are incorporated herein by reference.

### BACKGROUND

The present application relates to transparent insulating films formed by reactive sputtering, methods for producing the transparent insulating films, and sputtering targets.

The development of electrowetting devices, which utilize electrowetting (electrocapillarity), has recently been pushed forward (for example, see PCT International Publication No. WO 99/18456). Electrowetting is a phenomenon in which a voltage applied between a conductive liquid and an electrode changes the solid-liquid interfacial energy between the electrode surface and the liquid, thereby changing the shape of the liquid surface.

A typical electrowetting device includes a first liquid that is conductive, a second liquid that is insulating, a pair of substrates (lower and upper substrates) forming a liquid chamber that contains the first and second liquids, an electrode layer formed on a surface of the lower substrate, and an insulating layer formed on a surface of the electrode layer (for example, see Japanese Unexamined Patent Application Publication No. 2003-302502). A voltage applied across the insulating layer between the first liquid, which is conductive, and the electrode layer changes the shape of the interface between the first and second liquids by electrowetting. If the first and second liquids have different refractive indices, a varifocal lens can be formed in which the shape of the interface between the two liquids changes reversibly with the voltage applied.

Recently, the development of reliable electrowetting devices capable of operating at low drive voltage has been demanded. An electrowetting device, as described above, operates in response to the voltage applied between the conductive liquid and the electrode layer. This drive voltage is proportional to the dielectric constant of the insulating layer between the conductive liquid and the electrode layer and is inversely proportional to the thickness of the insulating layer. Hence, a thinner insulating layer formed of a material With a higher dielectric constant allows the electrowetting device to operate at a lower drive voltage.

An example of an insulating material with a high dielectric constant is a sputtered film formed of an insulating inorganic crystalline material, such as a metal oxide film, for example, a ZnO-based insulating film. According to a method of the related art, a ZnO-based insulating film is formed by reactive sputtering using a zinc metal target (zinc: 100% by weight). The resultant insulating film, however, has poor surface flatness with minute protrusions (hillocks) because ZnO crystallizes easily during the film formation. This results in dielectric breakdown and degraded withstand voltage characteristics, thus making it difficult to form a stable insulating film. That is, a current leakage can occur between the conductive liquid and the insulating film (high-dielectric-constant film) formed in the electrowetting device in its local irregular peak regions, thus raising the risk of dielectric breakdown in the insulating film.

### SUMMARY

It is desirable to provide a thin transparent insulating film with superior withstand voltage characteristics, a method for producing such a transparent insulating film, and a sputtering target for use in the production method.

A method for producing a transparent insulating film according to an embodiment includes a step of forming a transparent insulating film on a substrate by sputtering using a zinc-aluminum alloy target containing 50% to 90% by weight zinc and 10% to 50% by weight aluminum in a mixed gas atmosphere of an inert gas and oxygen gas.

The proportion of the flow rate (sccm) of the oxygen gas to that of the mixed gas in the step of forming the transparent insulating film is preferably 20% to 80%.

A transparent insulating film according to another embodiment is formed on a substrate by the above method for producing a transparent insulating film.

The transparent insulating film is preferably amorphous. In addition, the transparent insulating film preferably has no minute protrusions. Furthermore, the transparent insulating film preferably withstands an electric field strength of 0.8 MV/cm or more.

A sputtering target according to another embodiment for forming a transparent insulating film on a substrate by reactive sputtering in a mixed gas atmosphere of an inert gas and oxygen gas is formed of a zinc-aluminum alloy containing 50% to 90% by weight zinc and 10% to 50% by weight aluminum.

The above method for producing a transparent insulating film can be used to form a transparent insulating film in a stable amorphous state that is flat and has no minute protrusions such as hillocks.

The above transparent insulating film is a flat transparent insulating film in a stable amorphous state that is suitable as, for example, a dielectric thin film for an electrowetting device.

The above sputtering target is suitable for forming by sputtering a transparent insulating film in a stable amorphous state that is flat and has no minute protrusions such as hillocks.

Additional features and advantages are described herein, and will be apparent from the following Detailed Description and the figures.

### BRIEF DESCRIPTION OF THE FIGURES

FIG. 1 is a schematic diagram showing the structure of a sputtering apparatus for use in a method for producing a transparent insulating film according to an embodiment;

FIG. 2 is a side sectional view showing the schematic structure of an electrowetting device;

FIG. 3 is a sectional view showing the schematic structure of an insulating layer of the electrowetting device shown in FIG. 2;

FIGS. 4A and 4B are graphs showing the results of X-ray diffractometry for Example 1 and Comparative Example 1, respectively;

FIGS. 5A and 5B are atomic force micrographs of Example 1 and Comparative Example 1, respectively; and

FIG. 6 is a graph showing the measurement results of the withstand voltage strength of Example 1 and Comparative Example 1.

### DETAILED DESCRIPTION

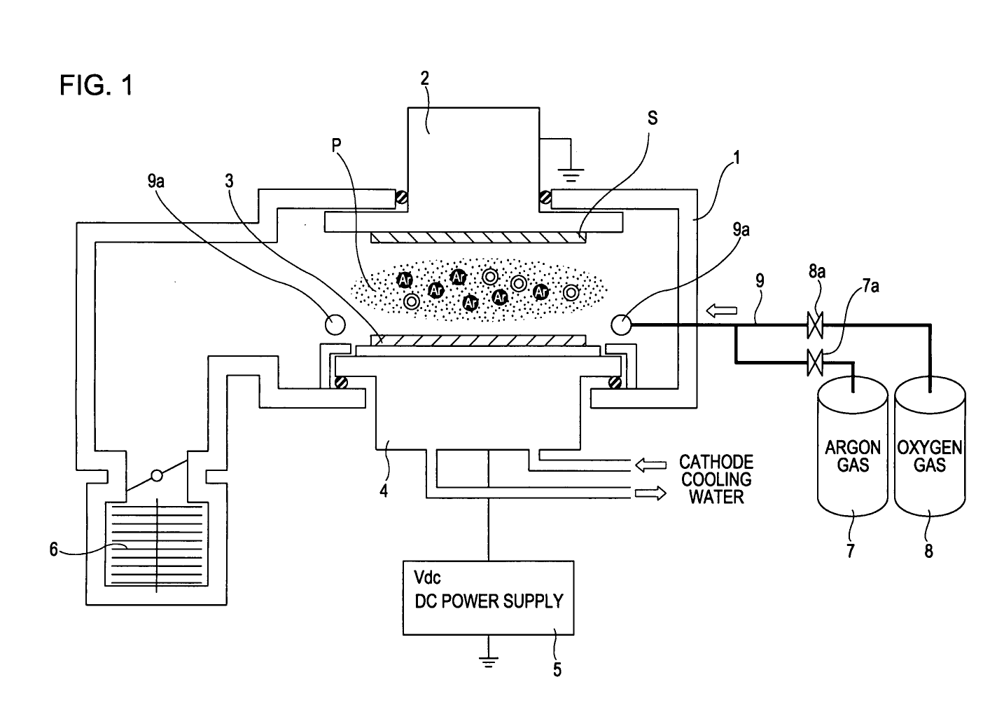

FIG. 1 is a schematic diagram showing the structure of a sputtering apparatus for use in the method for producing a transparent insulating film according to this embodiment.

Referring to FIG. 1, the sputtering apparatus is a DC sputtering apparatus that includes a substrate holder 2 holding a substrate S in a chamber 1 and a target holder 4 holding a target 3 in the chamber 1. The substrate holder 2 and the target holder 4 are disposed opposite each other so that a voltage can be applied between the substrate S and the target 3. Specifically, the substrate S is grounded via the substrate holder 2, whereas the target 3 is connected to a DC power supply 5 via the target holder 4. The DC power supply 5 applies a predetermined negative voltage to the target 3 with respect to the ground potential of the substrate S.

The sputtering apparatus also includes a vacuum pump 6 as an evacuation system in the chamber 1. In addition, the sputtering apparatus includes an argon gas tank 7, an oxygen gas tank 8, and gas piping 9 as a gas supply system. The argon gas tank 7 contains argon gas as an inert gas (sputtering gas), whereas the oxygen gas tank 8 contains oxygen gas as a reactive gas. These two gases are supplied into the chamber 1 through the gas piping 9 while being mixed midway in the gas piping 9. The gas piping 9 has an argon-gas-flow-rate controller 7a and an oxygen-gas-flow-rate controller 8a to control the proportions of the respective flow rates and the flow rate of the mixed gas before introducing the mixed gas into the chamber 1 through process gas inlets 9a.

A transparent insulating film is formed on the substrate S using the above sputtering apparatus by the following process.

(S11) The substrate S is set to the substrate holder 2. Any substrate may be used as the substrate S for various purposes. To form an electrowetting device, for example, a transparent polymer substrate on which an electrode layer and a crystalline insulating film are formed may be used.

(S12) The target 3 is set to the target holder 4. The target 3 used is a sputtering target formed of a zinc-aluminum alloy containing 50% to 90% by weight zinc and 10% to 50% by weight aluminum, with the balance being oxygen and incidental impurities.

(S13) The vacuum pump 6 is used to evacuate the chamber 1.

(S14) While the evacuation is continued, a mixed gas containing argon gas and oxygen gas in predetermined proportions is introduced from the argon gas tank 7 and the oxygen gas tank 8 into the chamber 1 through the process gas inlets 9a to maintain a predetermined atmospheric pressure (for example, 0.1 to 1.0 Pa) inside the chamber 1a. The proportion between the flow rates (sccm) of the gases being mixed (the proportion of the flow rate of the reactive gas) is adjusted so that the transparent insulating film to be formed has insulating properties with a predetermined resistance. That is, oxygen is introduced into the film in excess amounts by adjusting the proportion of the reactive gas flow rate and the power supplied so that the film has insulating properties. The proportion of the reactive gas flow rate is preferably 20% to 80%.

(S15) The DC power supply 5 is used to apply a DC voltage between the target 3 and the substrate S. This generates a glow discharge in the atmospheric gas (oxygen and argon), thus creating a plasma P.

(S16) Sputtering is started by supplying power (for example, 0.1 to 7.8 W/cm²) from the DC power supply 5, forming a transparent insulating film 1a based on the target composition on the substrate S. The sputtering is terminated when the transparent insulating film 1a is deposited to a predetermined thickness.

The above method for producing a transparent insulating film according to this embodiment can be used to form a transparent insulating film in a stable amorphous state that shows a flat surface texture without minute protrusions (hillocks) and that withstands an electric field strength of 0.8 MV/cm or more, even if the film is thin, namely, about 100 nm thick. In addition, this transparent insulating film can be applied to in electrowetting device.

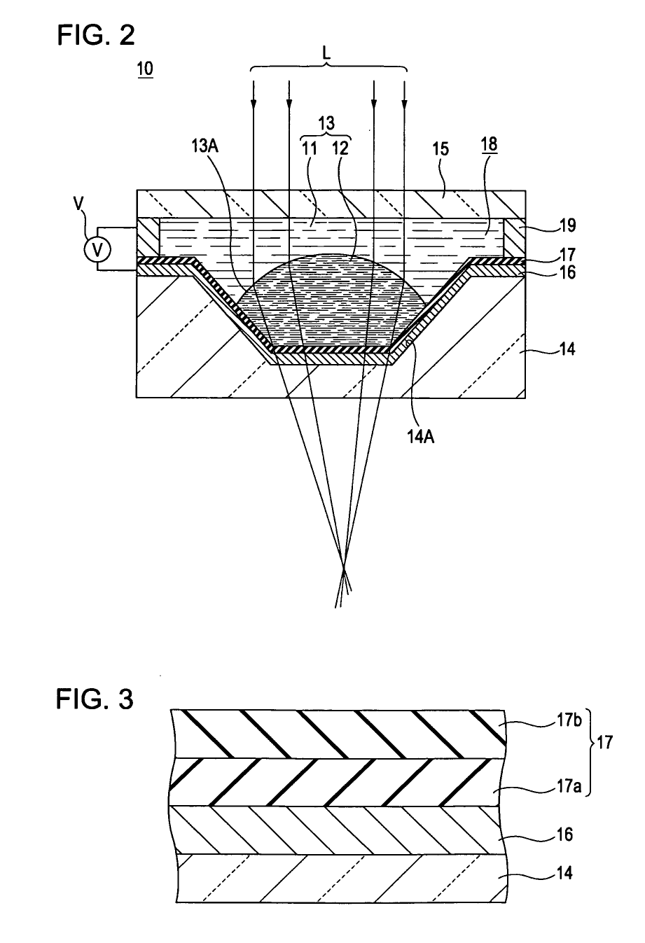

FIG. 2 is a side sectional view showing the schematic structure of an electrowetting device 10 including the transparent insulating film according to this embodiment. The electrowetting device 10 according to this embodiment includes a lens element 13 that forms a lens surface at an interface 13A between a first liquid 11 and a second liquid 12 contained in a hermetic liquid chamber 18. The first liquid 11 is conductive, whereas the second liquid 12 is insulating. The electrowetting device 10 is used for an illumination optical system or a camera flash, for example, and is configured as a varifocal lens element, that is, a lens element in which the focal length of light L passing through the electrowetting device 10 can be freely changed.

The first liquid 11 used may be a transparent conductive liquid, for example, a polar liquid such as water, an electrolytic solution (e.g., an aqueous solution of an electrolyte such as potassium chloride, sodium chloride, or lithium chloride), an alcohol of low molecular weight (e.g., methyl alcohol or ethyl alcohol), or an ambient-temperature molten salt (e.g., an ionic liquid).

The second liquid 12 used may be a transparent insulating liquid, for example, a nonpolar solvent such as a hydrocarbon (e.g., decane, dodecane, hexadecane, or undecane), silicone oil, or a fluorinated material. In this embodiment, the second liquid 12 used is, but not limited to, a liquid having a higher surface tension than the first liquid 11.

The materials selected for the first liquid 11 and the second liquid 12 are immiscible and have different refractive indices. In this embodiment, specifically, the first liquid 11 used is a lithium chloride aqueous solution (concentration: 3.66% by weight; refractive index: 1.34), whereas the second liquid 12 used is silicone oil (TSF437, manufactured by GE Toshiba Silicone Co., Ltd.; refractive index: 1.49). In addition, the first liquid 11 and the second liquid 12 preferably have similar specific gravities. If necessary, the first liquid 11 and the second liquid 12 may be colored.

The liquid chamber 18 is formed inside a container constituted by stacking a pair of substrates, namely, a transparent substrate 14 and a lid 15, on top of each other.

The transparent substrate 14 and the lid 15 are formed of an optically transparent insulating material such as an injection-molded plastic, glass, or a ceramic. Preferred examples of plastics include transparent polymers such as polycarbonate (PC), polyethylene terephthalate (PET), polyethylene naphthalate (PEN), polyethersulfone (PES), and polyolefin (PO).

In this embodiment, a recess 14A is formed in a surface of the transparent substrate 14 on the liquid chamber 18 side to accommodate the lens element 13. The shape of the surface of the transparent substrate 14 is not limited to the above example and may be any shape. For example, a flat surface may instead be formed.

An electrode layer 16 is formed on the surface of the transparent substrate 14 on the liquid chamber 18 side. The electrode layer 16 is formed of a transparent electrode material. In this embodiment, the electrode layer 16 is formed of a sputtered film of at least two metal oxides selected from a group including ZnO, for example, a sputtered film of ZnO—Al₂O₃ (AZO), although the film used is not limited thereto and may instead be, for example, indium tin oxide (ITO), ZnO—Ga₂O₃ (GZO), or ZnO—SiO₂ (SZO).

An insulating layer 17 is formed on the electrode layer 16. FIG. 3 is a sectional view of the electrode layer 16 and its vicinity, showing the structure of the insulating layer 17. The insulating layer 17 has a multilayer structure including a first insulating film 17a formed of an insulating inorganic crystalline material on the electrode layer 16 and a second insulating film 17b formed of an insulating inorganic amorphous material on the first insulating film 17a.

The first insulating film 17a is a transparent oxide film formed by a vacuum thin-film formation technique such as sputtering or vacuum deposition. The first insulating film 17a itself is a crystalline insulating film, whereas the second insulating film 17b itself is an amorphous insulating film. The second insulating film 17b is formed on the first insulating film 17a, which is crystalline, to cover irregularities on the surface of the first insulating film 17a.

As the first insulating film 17a, a high-dielectric-constant film formed of, for example, ZnO, Al₂O₃, MgO, HfO₂, ZrO₂, Fe₂O₃, or TiO₂ is suitable. As the second insulating film 17b, on the other hand, the transparent insulating film according to this embodiment is suitable.

In this embodiment, the first insulating film 17a is formed of ZnO, whereas the second insulating film 17b is formed of ZnAlO; that is, they are formed of the oxides containing the same metal element. This increases the compatibility and therefore adhesion between the two insulating films 17a and 17b. In addition, the metal element is also contained in the material (AZO) of the electrode layer 16. This increases the adhesion between the electrode layer 16 and the first insulating film 17a and also increases the degree of crystal orientation of the first insulating film 17a to provide a higher dielectric constant.

The thicknesses of the first insulating film 17a and the second insulating film 17b are not particularly limited, although in this embodiment the thickness of the second insulating film 17b is similar to or smaller than that of the first insulating film 17a. This is because the first insulating film 17a, having a higher dielectric constant due to its crystallinity than the second insulating film 17b, predominantly determines the dielectric constant of the insulating layer 17. In addition, the second insulating film 17b does not require more than enough thickness to alleviate the surface roughness of the first insulating film 17a. Furthermore, the insulating layer 17 preferably has a liquid-repellent surface. From this viewpoint, the transparent insulating film according to this embodiment is suitable as the second insulating film 17b.

The insulating layer 17 is formed over the entire region where the electrode layer 16 is formed to prevent an electrical short-circuit between the electrode layer 16 and the first liquid 11, which is conductive. The insulating layer 17 is disposed opposite the lid 15 With an electrode member 19 therebetween. The electrode member 19 functions to apply an external voltage to the first liquid 11 and to seal the liquid chamber 18 between the transparent substrate 14 and the lid 15.

The electrowetting device 10, thus configured, according to this embodiment is provided with a voltage supply V for applying a drive voltage between the electrode layer 16 and the electrode member 19 (first liquid 11). The shape of the interface 13A between the first liquid 11 and the second liquid 12 is spherical or aspherical, with its curvature varying with the drive voltage supplied from the voltage supply V. The interface 13A forms a lens surface whose lens power depends on the difference in refractive index between the first liquid 11 and the second liquid 12. The drive voltage can therefore be controlled to change the focal length of the light L entering the transparent substrate 14 through the lid 15.

### EXAMPLES

An example and a comparative example will now be described.

### Example 1

A transparent insulating film (ZnAlO insulating film) was prepared as a sample for evaluation of crystallinity and surface flatness using the sputtering apparatus shown in FIG. 1 under the following conditions:

Substrate S: silicon wafer substrate (substrate temperature: room temperature)

Target 3: zinc-aluminum alloy target (zinc: 70% by weight; aluminum: 30% by weight)

Proportion of reactive gas flow rate: 60% (argon: 32 sccm; oxygen: 48 sccm)

(Proportion of reactive gas flow rate)=(oxygen gas flow rate)/{(oxygen gas flow rate)+(argon gas flow rate)}×100 (%)

Deposition rate: 2.5 nm/min

Thickness: 179 nm (actual measurement)

In addition, a sample for evaluation of insulation properties was prepared using the sputtering apparatus shown in FIG. 1 under the following conditions:

Substrate S: glass substrate (substrate temperature: room temperature)

(i) First Layer (Transparent Conductive Film)

Target 3: AZO target (ZnO-2 wt % Al₂O₃)

Proportion of reactive gas flow rate: appropriate to ensure conductivity

Thickness: 100 nm

(ii) Second Layer (Transparent Insulating Film)

Target 3: zinc-aluminum alloy target (zinc: 70% by weight; aluminum: 30% by weight)

Proportion of reactive gas flow rate: 60% (argon; 32 sccm; oxygen: 48 sccm)

Deposition rate: 2.5 nm/min

Thickness: 100 nm

(iii) Third Layer (Electrode Film)

Target 3: aluminum metal target

Introduced gas: argon gas

### Comparative Example 1

An insulating film (ZnO insulating film) was prepared as a sample for evaluation of crystallinity and surface flatness using the sputtering apparatus shown in FIG. 1 under the following conditions:

Substrate S: silicon wafer substrate (substrate temperature: room temperature)

Target 3: zinc metal target

Proportion of reactive gas flow rate: 60% (argon: 32 sccm; oxygen: 48 sccm)

(Proportion of reactive gas flow rate)=(oxygen gas flow rate)/{(oxygen gas flow rate)+(argon gas flow rate)}×100 (%)

Deposition rate: 2.5 nm/min

Thickness: 167 nm (actual measurement)

In addition, a sample for evaluation of insulation properties was prepared under the same conditions as in Example 1 except that the second layer was formed by the following conditions:

Target 3: zinc metal target

Proportion of reactive gas flow rate: 60% (argon: 32 sccm; oxvgen: 48 sccm)

Deposition rate: 2.5 nm/min

Thickness: 100 nm

The samples thus prepared were evaluated for crystallinity, surface flatness, and insulation properties. The results are as follows.

(1) Crystallinity

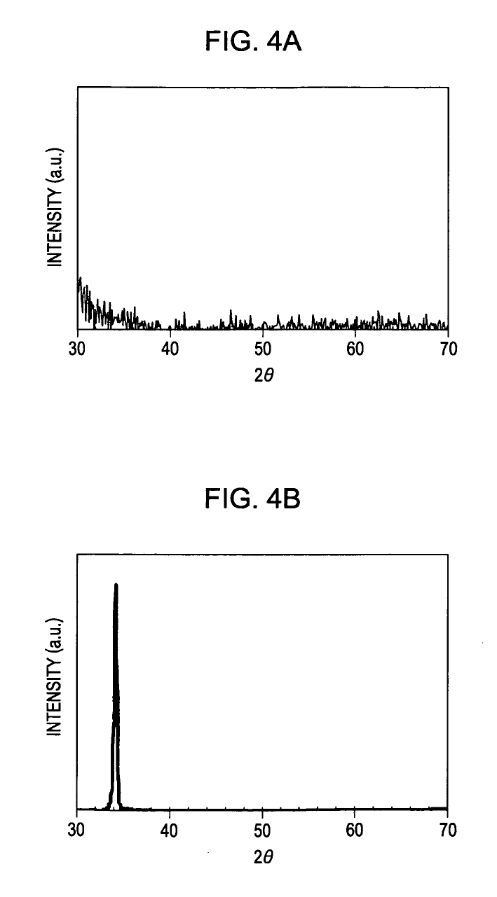

The results of X-ray diffractometry (XRD) are shown in FIGS. 4A and 4B.

According to FIG. 4A, the ZnAlO insulating film of Example 1 was found to be amorphous because it showed no clear peak. According to FIG. 4B, in contrast, the sample of Comparative Example 1 (ZnO insulating film) was found to be crystalline and have c-axis orientation because it showed a strong peak at ZnO(002).

(2) Surface Flatness

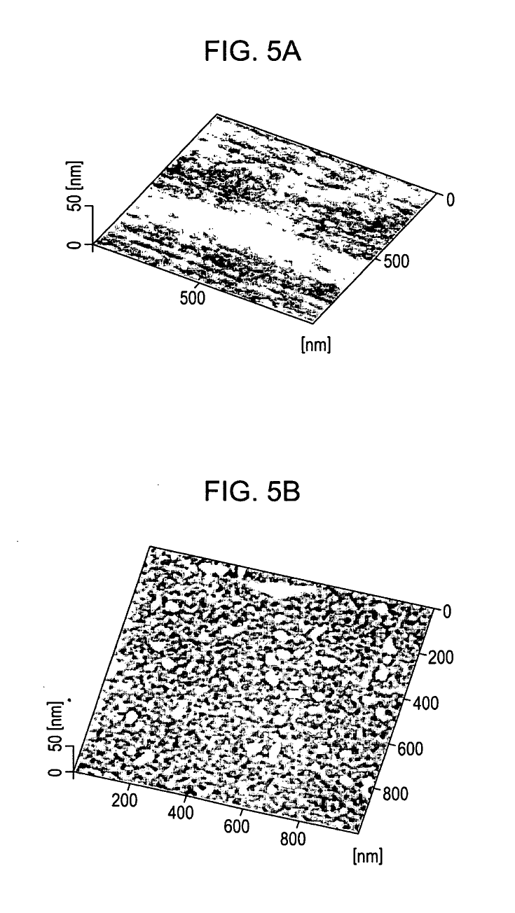

The surface conditions of the samples were examined using an atomic force microscope (AFM). The results are shown in FIGS. 5A and 5B. FIG. 5A shows that the sample of Example 1 (ZnAlO insulating film) had a smooth surface without minute protrusions (hillocks) as seen on the sample of Comparative Example 1 (FIG. 5B). In addition, the sample of Example 1 had an average surface roughness (Ra) of 0.26 nm, meaning that the sample had excellent flatness. In contrast, FIG. 5B shows the sample of Comparative Example 1 (ZnO insulating film) had a surface texture with aggregated minute crystals forming minute protrusions (hillocks). In addition, the sample of Comparative Example 1 had an average surface roughness (Ra) of 0.8 nm.

(3) Insulation Properties

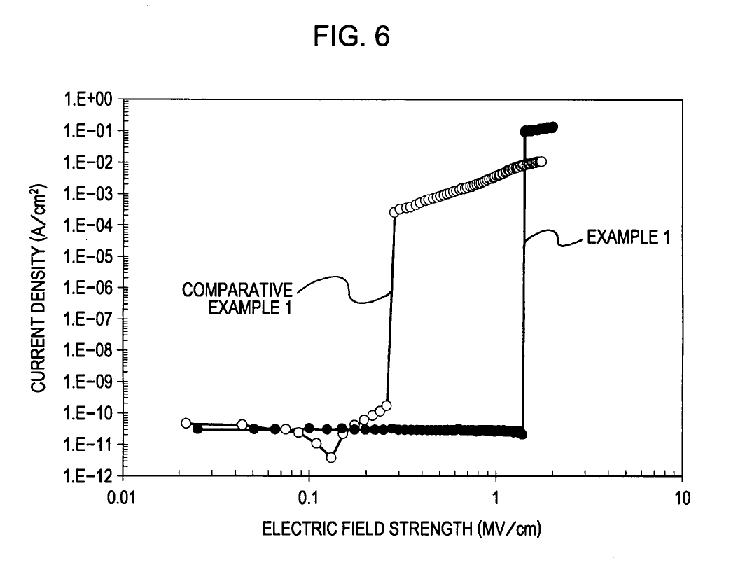

FIG. 6 shows the results of measurement of withstand voltage strength as an evaluation of insulation properties.

The electric field strength at which a dielectric breakdown occurred was 0.26 MV/cm for the sample of Comparative Example 1 and was 1.41 MV/cm for the sample of Example 1. These results demonstrate that the sample of Example 1 had superior withstand voltage characteristics.

Table 1 summarizes the results of the above measurements. Thus, the method for producing a transparent insulating film according to the above embodiment can be used to form a stable amorphous insulating film suitable for an electrowetting device.

TABLE 1

| | | | | Withstand |
|---|---|---|---|---|
| | | | Surface | voltage |
| | | | roughness | strength |
| | Crystal structure | Surface texture | (nm) | (MV/cm) |
| Example 1 | Amorphous | No minute | 0.26 | 1.41 |
| | | protrusions | | |
| Comparative | Good crystallinity | Minute | 0.80 | 0.26 |
| Example 1 | (002)-preferred | protrusions | | |
| | orientation | | | |

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A method for producing a transparent insulating film, comprising forming a transparent insulating film on a substrate by sputtering using a zinc-aluminum alloy target containing 50% to 90% by weight zinc and 10% to 50% by weight aluminum in a mixed gas atmosphere of an inert gas and oxygen gas.

2. The method for producing a transparent insulating film according to claim 1, wherein the proportion of the flow rate (sccm) of the oxygen gas to that of the mixed gas in the step of forming the transparent insulating film is 20% to 80%.

3. A transparent insulating film formed on a substrate by sputtering using a zinc-aluminum alloys target containing 50% to 90% by weight zinc and 10% to 50% by weight aluminum in a mixed gas atmosphere of an inert gas and oxygen gas.

4. The transparent insulating film according to claim 3, wherein the film is amorphous.

5. The transparent insulating film according to claim 3, wherein the film has no minute protrusions.

6. The transparent insulating film according to claim 3, wherein the film withstands an electric field strength of 0.8 MV/cm or more.

7. A sputtering target for forming a transparent insulating film on a substrate by reactive sputtering in a mixed gas atmosphere of an inert gas and oxygen gas, the sputtering target comprising a zinc-aluminum alloy containing 50% to 90% by weight zinc and 10% to 50% by weight aluminum.
